(19) United States
(12) Patent Application Publication
(10) Pub. No.: US 2026/0215191 A1
(43) Pub. Date: Jul. 23, 2026

(54) METHOD OF FABRICATING SEMICONDUCTOR PACAKGE

(71) Applicant: Taiwan Semiconductor Manufacturing Company, Ltd., Hsinchu (TW)

(72) Inventors: Ming-Tsu Chung, Hsinchu City (TW); Yung-Chi Lin, New Taipei City (TW); Kuo-Chiang Ting, Hsinchu City (TW); Yi-Hsiu Chen, Hsinchu City (TW); Ken-Yu Chang, Hsinchu City (TW)

(73) Assignee: Taiwan Semiconductor Manufacturing Company, Ltd., Hsinchu (TW)

(21) Appl. No.: 19/034,414

(22) Filed: Jan. 22, 2025

(51) Int. Cl. H01L 21/304; H01L 21/48; H01L 21/683; H01L 23/00; H01L 23/538; H01L 25/065

(52) U.S. Cl. CPC H10P 52/00; H10P 72/74; H10W 70/093; H10W 90/00; H10W 70/611; H10W 80/312; H10W 80/327; H10W 90/401

(57) ABSTRACT

A method of fabricating a semiconductor package includes forming a first package by the following steps. Semiconductor chips are bonded on an interconnection structure. A gap fill layer is formed on the interconnection structure and covering the semiconductor chips. A first planarization step is performed using a grinding wheel to remove a first portion of the gap fill layer. A second planarization step is performed by chemical-mechanical polishing using a polishing pad with a chemical slurry to remove a second portion of the gap fill layer, wherein backsides of the semiconductor chips is revealed after the second planarization step. A carrier is bonded on the backsides of the semiconductor chips. Conductive bumps are formed on the interconnection structure to obtain the first package. The first package is bonded on a circuit substrate by joining the conductive bumps to conductive pads of the circuit substrate.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the critical dimensions of the various features may be arbitrarily increased or reduced for clarity of discussion.

FIG. 1 to FIG. 9 are schematic sectional views of various stages in a method of fabricating a semiconductor package according to some exemplary embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The formation of semiconductor chips/dies on an interconnection structure (or on a wafer or interposer) generally includes forming a gap fill layer that laterally surrounds the semiconductor chips. However, the planarization step performed to remove the gap fill layer may include a chemical-mechanical polishing (CMP) step with a large RA (removal amount) of the gap fill layer. Due to the large RA, a dishing on backsides of the semiconductor chips may occur. To compensate for the dishing effect, bonding films formed on the backsides of the semiconductor chips generally have a greater thickness, which results in a higher thermal resistance in the semiconductor package.

In accordance with some embodiments of the present disclosure, a method of fabricating a semiconductor package is described, whereby an amount of dishing on the backsides of the semiconductor chips is minimized, a thickness of the bonding films formed on the backsides of the semiconductor chips is reduced, and a reduction in thermal resistance can be achieved.

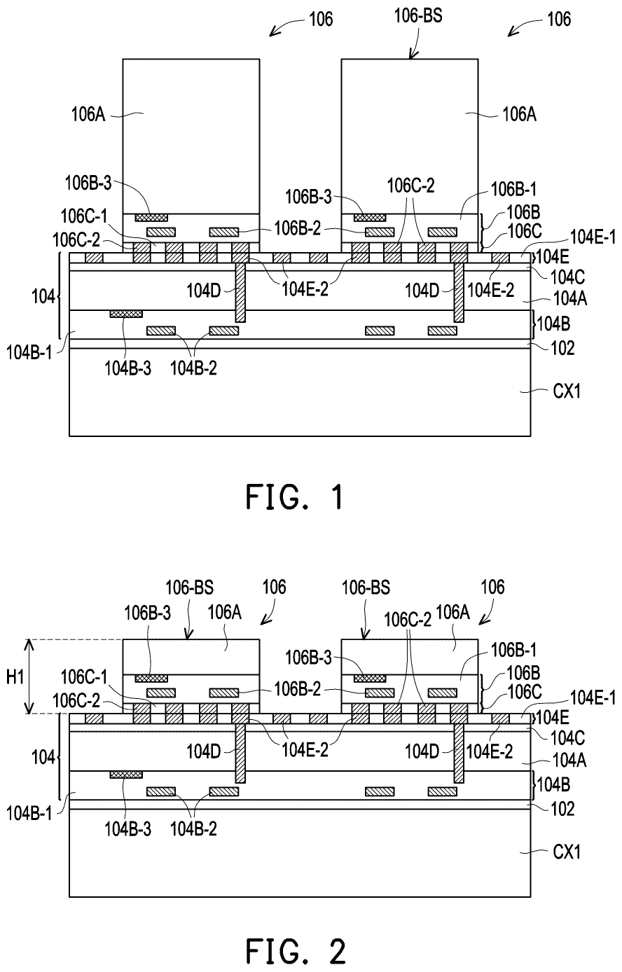

FIG. 1 to FIG. 9 are schematic sectional views of various stages in a method of fabricating a semiconductor package according to some exemplary embodiments of the present disclosure. As illustrated in FIG. 1, a first carrier CX1 is provided. In some embodiments, the first carrier CX1 may be a glass carrier or any suitable carrier for carrying a semiconductor wafer or a reconstituted wafer for the manufacturing method of the semiconductor package. In some embodiments, the first carrier CX1 is coated with a debond layer 102. The material of the debond layer 102 may be any material suitable for bonding and de-bonding the first carrier CX1 from the above layer(s) or any wafer(s) disposed thereon.

In some embodiments, the debond layer 102 may include a dielectric material layer made of a dielectric material including any suitable polymer-based dielectric material (such as benzocyclobutene (“BCB”), polybenzoxazole (“PBO”)). In an alternative embodiment, the debond layer 102 may include a dielectric material layer made of an epoxy-based thermal-release material, which loses its adhesive property when heated, such as a light-to-heat-conversion (LTHC) release coating film. In a further alternative embodiment, the debond layer 102 may include a dielectric material layer made of an ultra-violet (UV) glue, which loses its adhesive property when exposed to UV lights. In certain embodiments, the debond layer 102 may be dispensed as a liquid and cured, or may be a laminate film laminated onto the first carrier CX1, or may be the like. The top surface of the debond layer 102, which is opposite to a bottom surface contacting the first carrier CX1, may be leveled and may have a high degree of coplanarity. In certain embodiments, the debond layer 102 is, for example, a LTHC layer with good chemical resistance, and such layer enables room temperature de-bonding from the first carrier CX1 by applying laser irradiation, however the disclosure is not limited thereto.

In an alternative embodiment, a buffer layer (not shown) may be coated on the debond layer 102, where the debond layer 102 is sandwiched between the buffer layer and the first carrier CX1, and the top surface of the buffer layer may further provide a high degree of coplanarity. In some embodiments, the buffer layer may be a dielectric material layer. In some embodiments, the buffer layer may be a polymer layer which made of polyimide, polybenzoxazole (PBO), benzocyclobutene (BCB), or any other suitable polymer-based dielectric material. In some embodiments, the buffer layer may be Ajinomoto Buildup Film (ABF), Solder Resist film (SR), or the like. In other words, the buffer layer is optional and may be omitted based on the demand, so that the disclosure is not limited thereto.

Referring to FIG. 1, in a subsequent step, an interconnection structure 104 is formed on the debond layer 102. In some embodiments, the interconnection structure 104 is a semiconductor wafer, or an interposer structure. In the exemplary embodiment, the interconnection structure 104 is formed with a semiconductor substrate 104A, a redistribution layer 104B, a passivation layer 104C, through substrate vias 104D, and a bonding layer 104E. The semiconductor substrate 104A may be a bulk silicon substrate or a silicon-on-insulator (SOI) substrate, and further includes active devices (e.g., transistors or the like) and optionally passive devices (e.g., resistors, capacitors, inductors or the like) formed therein, or located thereon. For example, a device 104B-3 (active or passive devices) may be located on the semiconductor substrate 104A, and embedded in the redistribution layer 104B.

As further illustrated in FIG. 1, the interconnection structure 104 is disposed on the debond layer 102 so that the redistribution layer 104B is sandwiched in between the semiconductor substrate 104A and the debond layer 102. In some embodiments, the formation of the redistribution layer 104B includes forming a plurality of dielectric layers 104B-1 and a plurality of conductive elements 104B-2 that are alternately stacked. The number of dielectric layers 104B-1 and the number of conductive elements 104B-2 is not particularly limited in the disclosure, and may be adjusted based on product requirements.

In some embodiments, a material of the dielectric layers 104B-1 may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the material of the dielectric layers 104B-1 may be formed by suitable fabrication techniques such as spin-on coating, chemical vapor deposition (CVD), plasma-enhanced chemical vapor deposition (PECVD) or the like. The disclosure is not limited thereto.

In some embodiments, the conductive elements 104B-2 may be made of conductive materials formed by electroplating or deposition, such as aluminum, titanium, copper, nickel, tungsten, and/or alloys thereof, which may be patterned using a photolithography and etching process. In some embodiments, the conductive elements 104B-2 may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

Referring to FIG. 1, the passivation layer 104C is formed on a surface of the semiconductor substrate 104A, opposite to a surface where the redistribution layer 104B is located. In some embodiments, the passivation layer 104C is formed by depositing a dielectric material, such as silicon oxide, silicon nitride, or the like, and performing a planarization process to remove the excess portions of the dielectric material to reveal the through substrate vias 104D. Furthermore, in some embodiments, the through substrate vias 104D extends from the redistribution layer 104B through the semiconductor substrate 104A towards a surface of the passivation layer 104C. For example, the through substrate vias 104D are electrically connecting the redistribution layer 104B to the bonding layer 104E.

In some embodiments, the bonding layer 104E is formed on the passivation layer 104C. For example, forming the bonding layer 104E includes forming a dielectric layer 104E-1 and a plurality of bonding pads 104E-2 embedded in the dielectric layer 104E-1. In some embodiments, the bonding pads 104E-2 are made of conductive materials formed by electroplating or deposition, and include materials such as copper, copper alloys, or other suitable metallic materials which may be patterned using a photolithography and etching process. Furthermore, the dielectric layer 104E-1 may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layer 104E-1 is formed by suitable fabrication techniques such as spin-on coating, chemical vapor deposition (CVD), plasma-enhanced chemical vapor deposition (PECVD) or the like. The disclosure is not limited thereto.

After forming the interconnection structure 104 on the debond layer 102 and on the first carrier CX1, a plurality of semiconductor chips 106 is bonded onto the interconnection structure 104. In the exemplary embodiment, each of the semiconductor chips 106 includes a semiconductor substrate 106A, a redistribution layer 106B and a bonding layer 106C. The semiconductor substrate 106A may be a bulk silicon substrate or a silicon-on-insulator (SOI) substrate, and further includes active devices (e.g., transistors or the like) and optionally passive devices (e.g., resistors, capacitors, inductors or the like) formed therein, or located thereon. For example, a device 106B-3 (active or passive devices) may be located on the semiconductor substrate 106A, and embedded in the redistribution layer 106B.

In some embodiments, the redistribution layer 106B is located on the semiconductor substrate 106A. Furthermore, after bonding the semiconductor chips 106 onto the interconnection structure 104, the redistribution layer 106B is located in between the semiconductor substrate 106A of the semiconductor chips 106 and the bonding layer 104C of the interconnection structure 104. In some embodiments, the formation of the redistribution layer 106B includes forming a plurality of dielectric layers 106B-1 and a plurality of conductive elements 106B-2 that are alternately stacked. The number of dielectric layers 106B-1 and the number of conductive elements 106B-2 is not particularly limited in the disclosure, and may be adjusted based on product requirements.

In some embodiments, a material of the dielectric layers 106B-1 may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the material of the dielectric layers 106B-1 may be formed by suitable fabrication techniques such as spin-on coating, chemical vapor deposition (CVD), plasma-enhanced chemical vapor deposition (PECVD) or the like. The disclosure is not limited thereto.

In some embodiments, the conductive elements 106B-2 may be made of conductive materials formed by electroplating or deposition, such as aluminum, titanium, copper, nickel, tungsten, and/or alloys thereof, which may be patterned using a photolithography and etching process. In some embodiments, the conductive elements 106B-2 may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In some embodiments, the bonding layer 106C is formed on the redistribution layer 106B. For example, forming the bonding layer 106C includes forming a dielectric layer 106C-1 and a plurality of bonding pads 106C-2 embedded in the dielectric layer 106C-1. In some embodiments, the bonding pads 106C-2 are made of conductive materials formed by electroplating or deposition, and include materials such as copper, copper alloys, or other suitable metallic materials which may be patterned using a photolithography and etching process. Furthermore, the dielectric layer 106C-1 may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layer 106C-1 is formed by suitable fabrication techniques such as spin-on coating, chemical vapor deposition (CVD), plasma-enhanced chemical vapor deposition (PECVD) or the like. The disclosure is not limited thereto.

In the exemplary embodiment, the semiconductor chips 106 are bonded onto the interconnection structure 104 by bonding the bonding layer 104E to the bonding layer 106C. For example, the dielectric layer 104E-1 is joined with the dielectric layer 106C-1 through dielectric-to-dielectric bonding, and the bonding pads 104E-2 are joined with the bonding pads 106C-2 through direct metal-to-metal bonding. In some embodiments, the bonding layer 104E is joined to the bonding layer 106C so that a portion of the bonding pads 104E-2 are revealed (uncovered) by the semiconductor chips 106. In other words, some of the bonding pads 104E-2 are dummy pads that do not have electrical connection with the semiconductor chips 106. Although two semiconductor chips 106 are illustrated as being bonded to the interconnection structure 104, it is noted that the number of semiconductor chips 106 bonded to the interconnection structure 104 is not limited thereto, and may be adjusted based on product requirements.

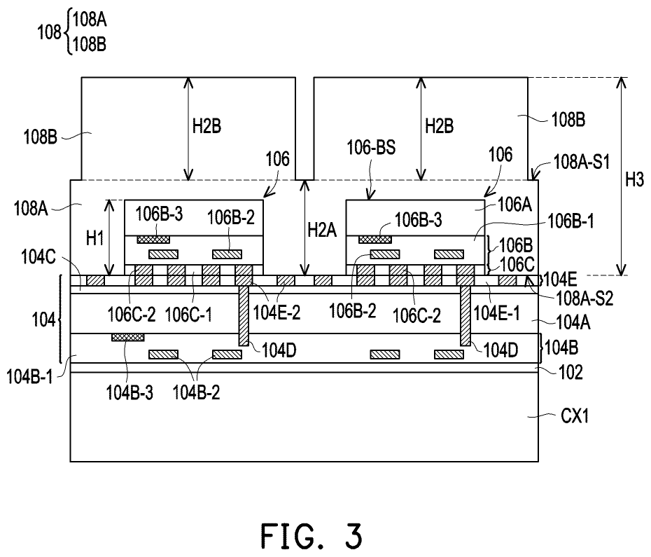

Referring to FIG. 2, in a subsequent step, backsides 106-BS of the semiconductor chips 106 are thinned down so that the semiconductor chips 106 have a first height H1. In some embodiments, the semiconductor chips 106 are thinned down by removing portions of the semiconductor substrate 106A. In the exemplary embodiment, the first height H1 of the thinned semiconductor chips 106 is 20 μm or less, but the disclosure is not limited thereto. In alternative embodiments, the first height H1 of the semiconductor chips 106 is more than 20 μm, which may be adjusted based on product requirements.

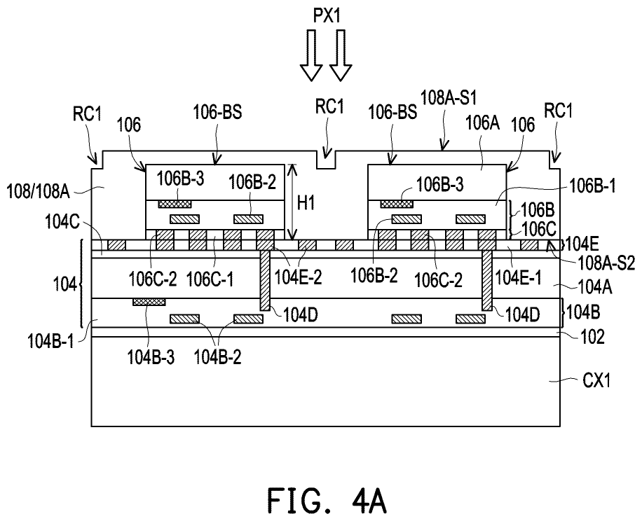

Referring to FIG. 3, in some embodiments, a gap fill layer 108 is formed on the interconnection structure 104 and covering the semiconductor chips 106. In some embodiments, the gap fill layer 108 may be formed of a dielectric material, such as an oxide such as silicon oxide, phosphosilicate glass (PSG), borosilicate glass (BSG), boron-doped phosphosilicate glass (BPSG), a tetraethyl orthosilicate (TEOS) based oxide, or the like, which may be formed by a suitable deposition process such as chemical vapor deposition (CVD), atomic layer deposition (ALD), or the like. In the exemplary embodiment, the gap fill layer 108 is conformally formed on the semiconductor chips 106 and on the interconnection structure 104 so that the gap fill layer 108 is formed with a first section 108A and a plurality of second sections 108B.

In some embodiments, the first section 108A is physically contacting the interconnection structure 104 and laterally surrounding the semiconductor chips 106. Furthermore, each of the plurality of second sections 108B is located on and protruding from the first section 108A and overlapped with each of the semiconductor chips 106. In some embodiments, the second section 108B is a protruding portion of the gap fill layer 108 that is formed above the semiconductor chips 106. In other words, in the case where one semiconductor chip 106 is present, there will be one corresponding second section 108B of the gap fill layer 108 that is formed above the one semiconductor chip 106. On the other hand, if there are two or more semiconductor chips 106 present, then there will be two or more second sections 108B of the gap fill layer 108 that is formed above the semiconductor chips 106. In certain embodiments, when two or more second sections 108B are present, the second sections 108B are separated from one another above a level of a top surface 108A-S1 of the first section 108A of the gap fill layer 108.

As further illustrated in FIG. 3, the first section 108A of the gap fill layer 108 has a top surface 108A-S1 and a bottom surface 108A-S2 opposite to the top surface 108A-S1. For example, the bottom surface 108A-S2 of the first section 108A is leveled with a surface of the bonding layer 106C of the semiconductor chips 106. Furthermore, the top surface 108A-S1 of the first section 108A is located above a level of the backsides 106-BS of the semiconductor chips 106. In other words, the top surface 108A-S1 of the first section 108A is kept a distance apart from the backsides 106-BS of the semiconductor chips 106.

In some embodiments, the first section 108A of the gap fill layer 108 has a height of H2A, which is measured from the bottom surface 108A-S2 to the top surface 108A-S1. Furthermore, the second section 108B of the gap fill layer 108 has a height of H2B, which is measured from the top surface 108A-S1 of the first section 108A towards a topmost surface of the gap fill layer 108. Furthermore, the first section 108A and the second section 108B of the gap fill layer 108 has a total height of H3. In the exemplary embodiment, the gap fill layer 108 is formed with the total height H3 that is greater than the height H1 of the semiconductor chips 106. In some embodiments, the height H2A of the first section 108A and the height H2B of the second section 108B of the gap fill layer 108 are greater than the height H1 of the semiconductor chips 106. For example, in one embodiment, when the height H1 of the semiconductor chips 106 is 20 μm or less, the height H2A of the first section 108A and the height H2B of the second section 108B are respectively more than 20 μm.

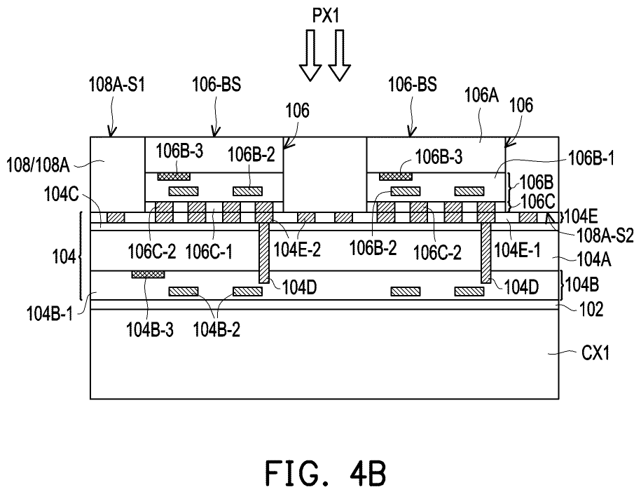

Referring to FIG. 4A to FIG. 4C, after forming the gap fill layer 108, a first planarization step PX1 is performed to remove portions of the gap fill layer 108. FIG. 4A to FIG. 4C illustrates various embodiments of performing the first planarization step PX1 due to process variations. In FIG. 4A to FIG. 4C, the first planarization step PX1 includes using a grinding wheel (not shown) for grinding and removing a portion of the gap fill layer 108, wherein a wheel pore ratio of the grinding wheel is greater than 50%, and a grit size of the grinding wheel is less than 12 μm.

As illustrated in FIG. 4A, in some embodiments, performing the first planarization step PX1 includes using the grinding wheel to completely remove the second sections 108B of the gap fill layer 108. As shown in FIG. 4A, the first planarization step PX1 further removes portions of the first section 108A of the gap fill layer 108 so that recesses RC1 are formed on a top surface 108A-S1 of the first section 108A of the gap fill layer 108. In some embodiments, the recesses RC1 extend to a level below backsides 106-BS of the semiconductor chips 106. However, the first section 108A is still covering the backsides 106-BS of the semiconductor chips 106.

As illustrated in FIG. 4B, in some embodiments, performing the first planarization step PX1 includes using the grinding wheel to completely remove the second sections 108B of the gap fill layer 108. Furthermore, the first planarization step PX1 further removes portions of the first section 108A of the gap fill layer 108 and portions of the backsides 106-BS of the semiconductor chips 106. For example, in the exemplary embodiment, the top surface 108A-S1 of the first section 108A of the gap fill layer 108 is substantially aligned or planar with the backsides 106-BS of the semiconductor chips 106 after the first planarization step PX1.

As illustrated in FIG. 4C, in some embodiments, performing the first planarization step PX1 includes using the grinding wheel to completely remove the second sections 108B of the gap fill layer 108. Furthermore, the first planarization step PX1 further removes portions of the first section 108A of the gap fill layer 108 so that recesses RC1 are formed on a top surface 108A-S1 of the first section 108A of the gap fill layer 108. In some embodiments, the recesses RC1 are defined by the top surface 108A-S1 of the first section 108A, and sidewalls of the semiconductor chips 106. Moreover, the top surface 108A-S1 of the first section 108A of the gap fill layer 108 is located at a level below backsides 106-BS of the semiconductor chips 106 after the first planarization step PX1. In other words, the backsides 106-BS of the semiconductor chips 106 are revealed after the first planarization step PX1.

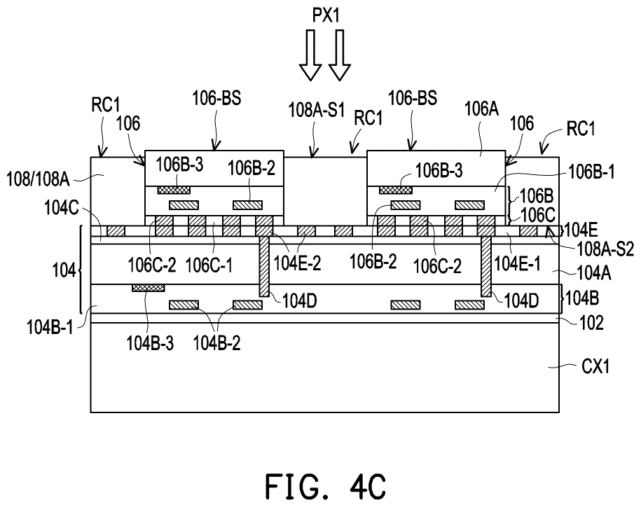

Referring to FIG. 5, after performing the first planarization step PX1 shown in any one of FIG. 4A to FIG. 4C, a second planarization step PX2 is performed to remove another portion of the gap fill layer 108. In some embodiments, the second planarization step PX2 and the first planarization step PX1 includes different planarization processes. For example, the second planarization step PX2 includes performing chemical-mechanical polishing (CMP) using a polishing pad with a chemical slurry having a slurry selectivity for oxide and silicon of 1:1.

In some embodiments, the second planarization step PX2 partially removes the first section 108A of the gap fill layer 108, and partially removes the backsides 106-BS of the semiconductor chips 106. In certain embodiments, the second planarization step PX2 is performed so that a removal amount RA1 (or removal height) of the gap fill layer 108 and/or the backsides 106-BS of the semiconductor chips 106 is controlled to be less than 8 μm. For example, the removal amount RA1 is in a range from 0.1 μm to less than 8 μm, and may be 7 μm, 6 μm, 5 μm, 4 μm, 3 μm, 2 μm, 1 μm or less than 1 μm. In the exemplary embodiment, the removal amount RA1 of the gap fill layer 108 performed in the second planarization step PX2 is less than a removal amount of the portions of the gap fill layer 108 performed in the first planarization step PX1. In some embodiments, a ratio (PX1:PX2) of the removal amount of the gap fill layer 108 in the first planarization step PX1 to the removal amount RA1 of the gap fill layer 108 in the second planarization step PX2 is in a range of 3:2 to 20:1, with the proviso that the removal amount RA1 is less than 8 μm. In the exemplary embodiment, when the removal amount RA1 of the gap fill layer 108 in the second planarization step PX2 is controlled in the above range, then an amount of dishing on backsides 106-BS of the semiconductor chips 106 are minimized. As such, the top surface 108A-S1 of the first section 108A of the gap fill layer 108 and backsides 106-BS of the semiconductor chips 106 may have a high degree of planarity.

In the exemplary embodiment, the backsides 106-BS of the semiconductor chips 106 are revealed after the second planarization step PX2. In some embodiments, a thickness difference of topography of the backsides 106-BS of the semiconductor chips 106 and a backside of the gap fill layer 108 (or top surface 108A-S1 of the first section 108A) is 300 angstroms or less. In certain embodiments, the thickness difference of topography of the backsides 106-BS of the semiconductor chips 106 and the backside of the gap fill layer 108 (or top surface 108A-S1 of the first section 108A) is 200 angstroms or less, or is 100 angstroms or less.

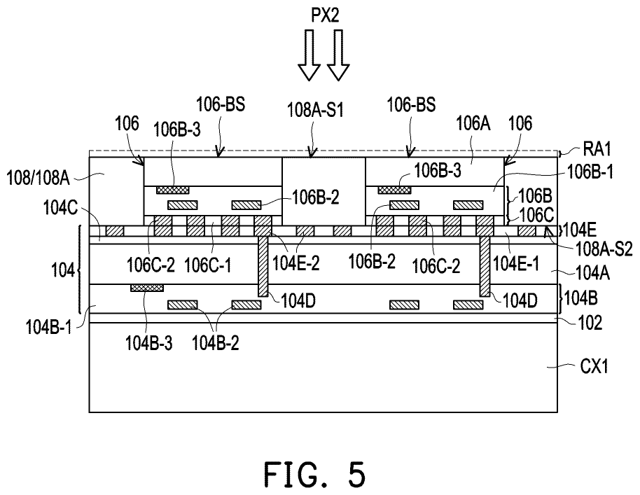

Referring to FIG. 6, after performing the second planarization step PX2 to reveal the backsides 106-BS of the semiconductor chips 106, a first bonding film 112 is formed on the backsides 106-BS of the semiconductor chips 106, and formed on the top surface 108A-S1 of the gap fill layer 108. In some embodiments, the first bonding film 112 is formed by thin film deposition techniques, such as atomic layer deposition (ALD), sputtering or the like. Furthermore, the first bonding film 112 may include materials selected from the group consisting of aluminum monoxide (AlO), aluminum nitride (AlN), silicon carbide (SiC), silicon carbonitride (SiCN), silicon nitride (SiN), silicon oxide (SiO₂), silicon monoxide (SiO), titanium nitride (TiN), or the like. In certain embodiments, the first bonding film 112 is silicon oxides such as tetramethoxysilane (TEOS), undoped silicon glass (USG), high-density plasma (HDP) oxides, atomic layer deposition (ALD) oxide, or thermal oxides. In some embodiments, due to a high degree of planarity at the backsides 106-BS of the semiconductor chips 106 and the backside of the gap fill layer 108 (or top surface 108A-S1 of the first section 108A), a film thickness of the first bonding film 112 is 2000 angstroms or less.

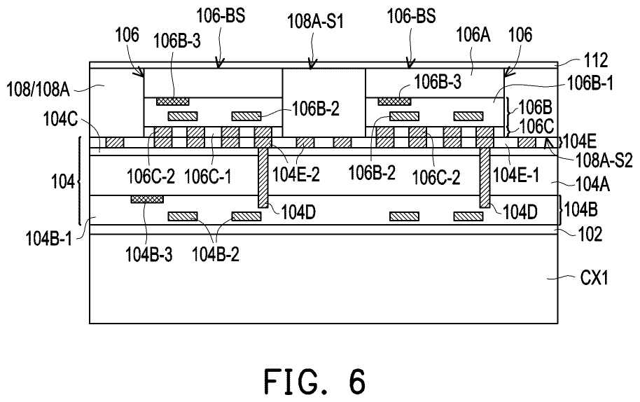

Referring to FIG. 7, in a subsequent step, a second carrier CX2 is bonded onto the backsides 106-BS of the semiconductor chips 106 and on the backside of the gap fill layer 108 (or on top surface 108A-S1 of the first section 108A). In some embodiments, the second carrier CX2 may be a glass carrier, or made by made from silicon, silicon carbide, aluminum nitride, diamond, or may be any suitable carrier for carrying a semiconductor wafer or a reconstituted wafer for the manufacturing method of the semiconductor package. In some embodiments, a second bonding film 120 is formed on the second carrier CX2 by thin film deposition techniques, such as atomic layer deposition (ALD), sputtering or the like. Furthermore, the second bonding film 120 may include materials selected from the group consisting of aluminum monoxide (AlO), aluminum nitride (AlN), silicon carbide (SiC), silicon carbonitride (SiCN), silicon nitride (SiN), silicon oxide (SiO₂), silicon monoxide (SiO), titanium nitride (TiN), or the like. In certain embodiments, the second bonding film 120 is silicon oxides such as tetramethoxysilane (TEOS), undoped silicon glass (USG), high-density plasma (HDP) oxides, atomic layer deposition (ALD) oxide, or thermal oxides.

In some embodiments, the second carrier CX2 is bonded to the first bonding film 112 located on the semiconductor chips 106 and on the gap fill layer 108 through the second bonding film 120. In other words, the second bonding film 120 is directly joined with the first bonding film 112. In some embodiments, a total thickness TX1 of the first bonding film 112 and the second bonding film 120 is less than 3000 angstroms. In certain embodiments, the total thickness TX1 corresponds to a distance in between the second carrier CX2 and the backsides 106-BS of the semiconductor chips 106. In some embodiments, by controlling the total thickness TX1, which is the carrier to die interface film thickness to less than 2000 angstroms, a reduction in thermal resistance can be achieved.

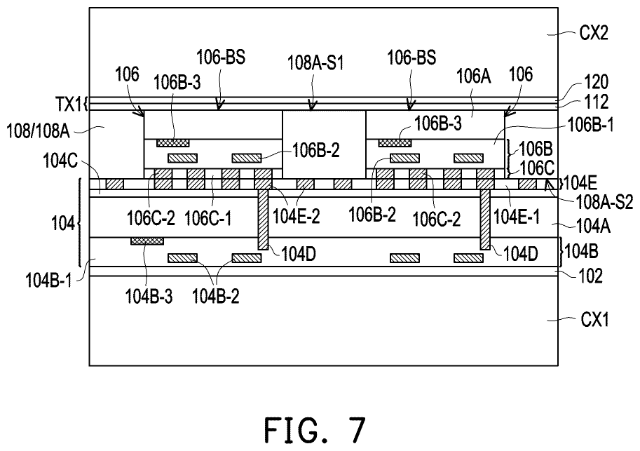

Referring to FIG. 8, after bonding the second carrier CX2 on the backsides 106-BS of the semiconductor chips 106, the structure shown in FIG. 7 is flipped around, and the first carrier CX1 is debonded/removed to separate the interconnection structure 104 from the first carrier CX1. In some embodiments, the debonding process include projecting a light such as a laser light or an UV light on the debond layer 102, so that the first carrier CX1 can be easily removed. As illustrated in FIG. 8, upon removing the first carrier CX1, a surface of the redistribution layer 104B is exposed. In some embodiments, the dielectric layers 104B-1 of the redistribution layer 104B are patterned to form openings revealing the conductive elements 104B-2. Thereafter, a plurality of conductive pads 130 are formed in the openings to be electrically connected to the conductive elements 104B-2. In some embodiments, the conductive pads 130 are for example, under-ball metallurgy (UBM) patterns used for ball mount. In some embodiments, the materials of the conductive pads 130 may include copper, nickel, titanium, tungsten, or alloys thereof or the like, and may be formed by an electroplating process, for example. The number of conductive pads 130 are not limited in this disclosure, and may be selected based on the design layout.

After forming the conductive pads 130, a plurality of conductive bumps 132 is disposed on the conductive pads 130 and over the interconnection structure 104. In some embodiments, the conductive bumps 132 may be disposed on the conductive pads 130 by a ball placement process or reflow process. In some embodiments, the conductive bumps 132 are solder bumps, lead-free solder bumps, or micro bumps, such as controlled collapse chip connection (C4) bumps or micro bumps containing copper pillars, or the like. In some embodiments, the conductive bumps 132 are electrically connected to the redistribution layer 104B of the interconnection structure 104 through the conductive pads 130. After forming the conductive pads 130 and conductive bumps 132, multiple first packages PK1 including the above package components are formed on the same carrier substrate(s) and then singulated to form an individual first package PK1.

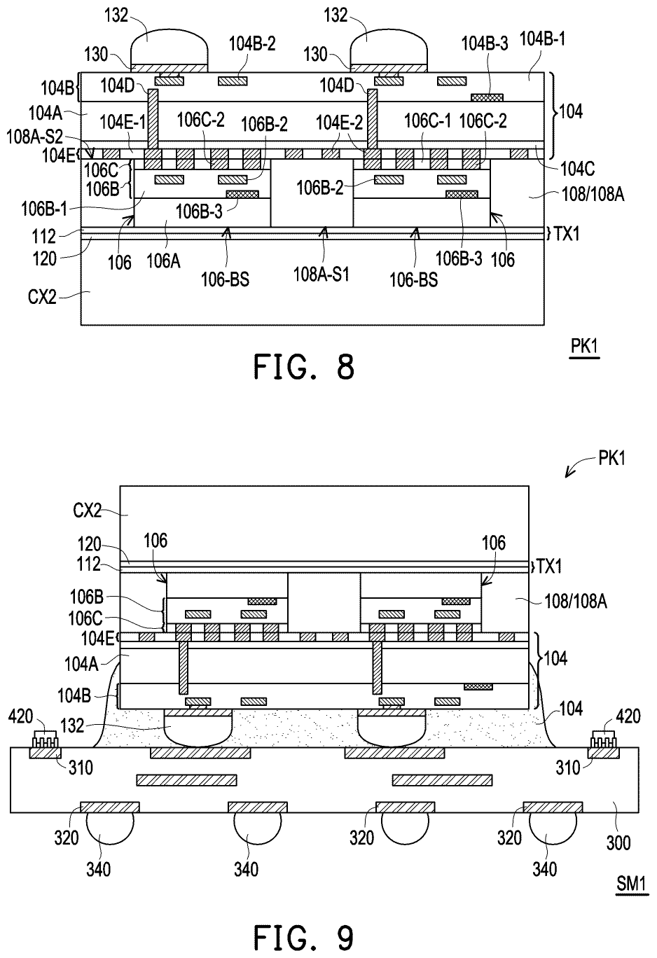

Referring to FIG. 9, in the exemplary embodiment, the first package PK1 obtained in FIG. 8 is mounted or attached onto a circuit substrate 300 through the conductive bumps 132. In some embodiments, the circuit substrate 300 includes contact pads 310, contact pads 320, metallization layers 330, and vias (not shown). In some embodiments, the contact pads 310 and the contact pads 320 are respectively distributed on two opposite sides of the circuit substrate 300, and are exposed for electrically connecting with later-formed elements/features. In some embodiments, the metallization layers 330 and the vias are embedded in the circuit substrate 300 and together provide routing function for the circuit substrate 300, wherein the metallization layers 330 and the vias are electrically connected to the contact pads 310 and the contact pads 320. In other words, at least some of the contact pads 310 are electrically connected to some of the contact pads 320 through the metallization layers 330 and the vias. In some embodiments, the contact pads 310 and the contact pads 320 may include metal pads or metal alloy pads. In some embodiments, the materials of the metallization layers 330 and the vias may be substantially the same or similar to the material of the contact pads 310 and the contact pads 320.

Furthermore, in some embodiments, the first package PK1 is bonded to the circuit substrate 300 through physically connecting the conductive bumps 132 and the contact pads 310 to form a stacked structure. In certain embodiments, the first package PK1 is electrically connected to the circuit substrate 300. In some embodiments, the circuit substrate 300 is such as an organic flexible substrate or a printed circuit board. In some embodiments, a plurality of conductive balls 340 are respectively formed on the substrate 300. As illustrated in FIG. 9, for example, the conductive balls 340 are connected to the contact pads 320 of the circuit substrate 300. In other words, the conductive balls 340 are electrically connected to the circuit substrate 300 through the contact pads 320. Through the contact pads 310 and the contact pads 320, some of the conductive balls 340 are electrically connected to the first package PK1. In some embodiments, the conductive balls 340 are, for example, solder balls or ball grid array (BGA) balls.

As further illustrated in FIG. 9, in some embodiments, passive devices 420 (integrated passive device or surface mount devices) may be mounted on the circuit substrate 300. For example, the passive devices 420 may be mounted on the contact pads 310 of the circuit substrate 300 through a soldering process. The disclosure is not limited thereto. In certain embodiments, the passive devices 420 may be mounted on the circuit substrate surrounding the first package PK1. In some embodiments, an underfill structure 410 is formed to fill up the spaces in between the circuit substrate 300 and the first package PK1. In certain embodiments, the underfill structure 410 fills up the spaces in between adjacent conductive bumps 132 and covers the conductive bumps 132. For example, the underfill structure 410 surrounds the plurality of conductive bumps 132. In some embodiments, the passive devices 420 is exposed by the underfill structure 410, and kept a distance apart from the underfill structure 410. In other words, the underfill structure 410 does not cover the passive devices 420. Up to here, a semiconductor package SM1 in accordance with some embodiments of the present disclosure is accomplished.

In the above-mentioned embodiments, the method of fabricating a semiconductor package includes forming a gap fill layer on an interconnection structure and covering a plurality of semiconductor chips. The gap fill layer is patterned by performing a first planarization step through grinding and performing a second planarization step through CMP using a polishing pad with a chemical slurry. By using such a method, an amount of dishing on the backsides of the semiconductor chips is minimized, a thickness of the bonding films formed on the backsides of the semiconductor chips is reduced, and a reduction in thermal resistance of the semiconductor package can be achieved.

In accordance with some embodiments of the present disclosure, a method of fabricating a semiconductor package includes the following steps. An interconnection structure is provided on a first carrier, wherein the interconnection structure includes a first bonding layer. A plurality of semiconductor chips is bonded on the interconnection structure, wherein the semiconductor chips includes a second bonding layer, and the second bonding layer is bonded to the first bonding layer. A gap fill layer is formed on the interconnection structure and covering the semiconductor chip. A first planarization step is performed to remove a first portion of the gap fill layer. A second planarization step is performed to remove a second portion of the gap fill layer to reveal backsides of the semiconductor chips, wherein a removal amount of the second portion of the gap fill layer is less than a removal amount of the first portion of the gap fill layer. A second carrier is bonded on the backsides of the plurality of semiconductor chips. The first carrier is removed, and a plurality of conductive bumps is formed on the interconnection structure.

In accordance with some other embodiments of the present disclosure, a method of fabricating a semiconductor package includes the following steps. A plurality of semiconductor chips is bonded on an interconnection structure. A gap fill layer is formed on the interconnection structure covering the semiconductor chips. Forming the gap fill layer includes conformally forming the gap fill layer on the semiconductor chips and on the interconnection structure so that the gap fill layer is formed with a first section and a plurality of second sections, wherein the first section is contacting the interconnection structure and laterally surrounding the semiconductor chips, and each of the second sections is located on and protruding from the first section and overlapped with the semiconductor chips, and wherein heights of the first section and the second section of the gap fill layer are greater than a height of the semiconductor chips. A first planarization step is performed to completely remove the second sections of the gap fill layer. A second planarization step is performed to partially remove the first section of the gap fill layer. A plurality of conductive bumps is formed on the interconnection structure.

In accordance with yet another embodiment of the present disclosure, a method of fabricating a semiconductor package includes forming a first package by the following steps. Semiconductor chips are bonded on an interconnection structure. A gap fill layer is formed on the interconnection structure and covering the semiconductor chips. A first planarization step is performed using a grinding wheel to remove a first portion of the gap fill layer. A second planarization step is performed by chemical-mechanical polishing using a polishing pad with a chemical slurry to remove a second portion of the gap fill layer, wherein backsides of the semiconductor chips is revealed after the second planarization step. A carrier is bonded on the backsides of the semiconductor chips. Conductive bumps are formed on the interconnection structure to obtain the first package. The first package is bonded on a circuit substrate by joining the conductive bumps to conductive pads of the circuit substrate.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor package, comprising:
providing an interconnection structure on a first carrier, wherein the interconnection structure comprises a first bonding layer;
bonding a plurality of semiconductor chips on the interconnection structure, wherein the plurality of semiconductor chips comprises a second bonding layer, and the second bonding layer is bonded to the first bonding layer;
forming a gap fill layer on the interconnection structure and covering the plurality of semiconductor chips;
performing a first planarization step to remove a first portion of the gap fill layer;
performing a second planarization step to remove a second portion of the gap fill layer to reveal backsides of the plurality of semiconductor chips, wherein a removal amount of the second portion of the gap fill layer is less than a removal amount of the first portion of the gap fill layer;
bonding a second carrier on the backsides of the plurality of semiconductor chips; and
removing the first carrier and forming a plurality of conductive bumps on the interconnection structure.

2. The method according to claim 1, wherein the first planarization step comprises using a grinding wheel for grinding the first portion of the gap fill layer, wherein a wheel pore ratio of the grinding wheel is greater than 50%, and a grit size of the grinding wheel is less than 12 μm.

3. The method according to claim 1, wherein the second planarization step comprises performing chemical-mechanical polishing using a polishing pad with a chemical slurry having a slurry selectivity for oxide and silicon of 1:1.

4. The method according to claim 1, wherein the removal amount of the second portion of the gap fill layer in the second planarization step is less than 8 μm, and a thickness difference of topography of the backsides of the plurality of semiconductor chips and a backside of the gap fill layer is 300 angstroms or less.

5. The method according to claim 1, wherein after performing the second planarization step to reveal the backsides of the plurality of semiconductor chips, a first bonding film is formed on the backsides of the plurality of semiconductor chips, and wherein bonding the second carrier on the backsides of the plurality of semiconductor chips comprises forming a second bonding film on the second carrier, and attaching the second bonding film to the first bonding film.

6. The method according to claim 5, wherein a total thickness of the first bonding film and the second bonding film is less than 2000 angstroms.

7. The method according to claim 1, wherein after bonding the plurality of semiconductor chips on the interconnection structure, the backsides of the plurality of semiconductor chips are thinned down so that the plurality of semiconductor chips have a first height, and wherein the gap fill layer is formed with a second height that is greater than the first height.

8. A method of fabricating a semiconductor package, comprising:
bonding a plurality of semiconductor chips on an interconnection structure;
forming a gap fill layer on the interconnection structure covering the plurality of semiconductor chips, wherein forming the gap fill layer comprises:
conformally forming the gap fill layer on the plurality of semiconductor chips and on the interconnection structure so that the gap fill layer is formed with a first section and a plurality of second sections, wherein the first section is contacting the interconnection structure and laterally surrounding the plurality of semiconductor chips, and each of the plurality of second sections is located on and protruding from the first section and overlapped with each of the plurality of semiconductor chips, and wherein heights of the first section and the second section of the gap fill layer are greater than a height of the plurality of semiconductor chips;
performing a first planarization step to completely remove the plurality of second sections of the gap fill layer;
performing a second planarization step to partially remove the first section of the gap fill layer; and
forming a plurality of conductive bumps on the interconnection structure.

9. The method according to claim 8, wherein the first planarization step further removes portions of the first section of the gap fill layer so that recesses are formed on a top surface of the first section of the gap fill layer.

10. The method according to claim 9, wherein the recesses extend to a level below backsides of the plurality of semiconductor chips.

11. The method according to claim 8, wherein the second planarization step partially removes the first section and partially removes backsides of the plurality of semiconductor chips, and a thickness difference of topography of the backsides of the plurality of semiconductor chips and a surface of the first section of the gap fill layer after the second planarization step is 300 angstroms or less.

12. The method according to claim 8, wherein the first planarization step comprises using a grinding wheel for grinding, and the second planarization step comprises performing chemical-mechanical polishing using a polishing pad with a chemical slurry.

13. The method according to claim 12, wherein a wheel pore ratio of the grinding wheel is greater than 50%, and a grit size of the grinding wheel is less than 12 μm, and wherein the chemical slurry has a slurry selectivity for oxide and silicon of 1:1.

14. The method according to claim 8, wherein a removal amount of the gap fill layer in the second planarization step is less than 8 μm.

15. The method according to claim 8, wherein the second planarization step is performed to reveal backsides of the plurality of semiconductor chips, and after the second planarization step, a first bonding film is formed on the backsides of the plurality of semiconductor chips, and wherein a carrier is bonded to the first bonding film through a second bonding film.

16. A method of fabricating a semiconductor package, comprising:
forming a first package, comprising:
bonding a plurality of semiconductor chips on an interconnection structure;
forming a gap fill layer on the interconnection structure and covering the plurality of semiconductor chips;
performing a first planarization step using a grinding wheel to remove a first portion of the gap fill layer;
performing a second planarization step by performing chemical-mechanical polishing using a polishing pad with a chemical slurry to remove a second portion of the gap fill layer, wherein backsides of the plurality of semiconductor chips is revealed after the second planarization step;
bonding a carrier on the backsides of the plurality of semiconductor chips; and
forming a plurality of conductive bumps on the interconnection structure to form the first package;
bonding the first package on a circuit substrate by joining the plurality of conductive bumps to contact pads of the circuit substrate.

17. The method according to claim 16, wherein a wheel pore ratio of the grinding wheel is greater than 50%, and a grit size of the grinding wheel is less than 12 μm in the first planarization step, and wherein the chemical slurry in the second planarization step has a slurry selectivity for oxide and silicon of 1:1.

18. The method according to claim 16, wherein forming the first package further comprises performing a thinning step to remove portions of the backsides of the plurality of semiconductor chips so that the plurality of semiconductor chips has a first height, and forming the gap fill layer comprises forming a first section surrounding the plurality of semiconductor chips and forming a plurality of second sections located on and protruding from the first section, wherein a height of the first section and a height of the second section of the gap fill layer are greater than the first height of the plurality of semiconductor chips.

19. The method according to claim 16, wherein a removal amount of the second portion of the gap fill layer in the second planarization step is less than 8 μm.

20. The method according to claim 16, further comprising forming an underfill structure surrounding the plurality of conductive bumps.
